(19) United States
(12) Patent Application Publication
(10) Pub. No.: US 2026/0127334 A1
(43) Pub. Date: May 7, 2026

(54) Automatic and Accurate Estimation Method for Gross Primary Productivity of Forest Ecosystem Based on Remote Sensing Technology

(71) Applicant: Sanya Research Base, International Center for Bamboo and Rattan, Sanya City (CN)

(72) Inventors: Huai Yang, Sanya City (CN); ShiRong Liu, Sanya City (CN); Biao Huang, Sanya City (CN); JiaLin Fu, Sanya City (CN); Shuangjia Fu, Sanya City (CN); Kai Bian, Sanya City (CN); JunWei Luan, Sanya City (CN); DaoChun Qin, Sanya City (CN); ChunJu Cai, Sanya City (CN); Li Ding, Sanya City (CN); XiangHua Yue, Sanya City (CN); JunHao Qiu, Sanya City (CN); Xin Tan, Sanya City (CN)

(73) Assignee: Sanya Research Base, International Center for Bamboo and Rattan, Sanya City (CN)

(21) Appl. No.: 19/186,635

(22) Filed: Apr. 23, 2025

(30) Foreign Application Priority Data
Nov. 5, 2024 (CN) 202411568894.4

(51) Int. Cl. G06F 30/20; A01G 23/00

(52) U.S. Cl. CPC G06F 30/20; A01G 23/00

(57) ABSTRACT

The automatic and accurate estimation method for gross primary productivity of a forest ecosystem based on a remote sensing technology includes: the real-time position signals of a remote sensing collection device is acquired, the forest map is acquired and the real-time position signals is displayed on the map; the meteorological parameters and forest characteristic parameters of the forest are collected by a remote sensing collection device, and the preliminary estimation on the GPP of the forest ecosystem is performed by a ground estimation model; the geomorphological features of the map are collected, it is judged whether to correct the preliminary estimation result according to the geomorphological features, and if the correction is needed, the preliminary estimation result is adjusted; and the adjusted estimation result is stored, and the dynamic fluctuation chart of the adjusted estimation result is displayed on a visual device.

### CROSS-REFERENCE TO RELATED APPLICATION

This patent application claims the benefit and priority of Chinese Patent Application No. 202411568894.4, entitled “AUTOMATIC AND ACCURATE ESTIMATION METHOD FOR GROSS PRIMARY PRODUCTIVITY OF FOREST ECOSYSTEM BASED ON REMOTE SENSING TECHNOLOGY” filed with the China National Intellectual Property Administration on Nov. 5, 2024, the disclosure of which is incorporated by reference herein in its entirety as part of the present application.

### TECHNICAL FIELD

The present disclosure relates to the field of forest gross primary productivity estimation technology, in particular to an automatic and accurate estimation method for gross primary productivity of a forest ecosystem based on a remote sensing technology.

### BACKGROUND

The remote sensing technology is a method to obtain information about an object or environment through detection devices (such as satellites, unmanned aerial vehicles, aircraft, etc.) without direct contact with the object being measured. This technology is mainly used to observe and analyze various natural phenomena on the earth's surface and in its atmosphere. The remote sensing technology is widely used, including environmental monitoring, resource investigation, disaster assessment, climate research and other fields. The Gross Primary Productivity (GPP) of the forest ecosystem refers to the total amount of carbon fixed by the forest ecosystem through photosynthesis in a certain period of time. It represents the process by which plants absorb carbon dioxide (CO₂) from the atmosphere and convert it into organic matter, and is a key link in the carbon cycle of the forest ecosystem.

The prior art often rely on ground surveys and traditional monitoring methods, which are affected by human interference, limited sample size and uneven geographical coverage, resulting in greater uncertainty in the estimation results. Traditional methods need to invest a lot of manpower, material resources and time to collect data and estimate data, which make the estimation process cumbersome and time-consuming, and it is difficult to meet the estimation requirements of fast, efficient and accurate.

Therefore, it is necessary to provide an automatic and accurate estimation method for GPP of a forest ecosystem based on a remote sensing technology, so as to solve the problem that the estimation for the GPP of the forest ecosystem is not efficient and accurate in the prior art.

### SUMMARY

In view of this, the present disclosure provides an automatic and accurate estimation method for GPP of a forest ecosystem based on a remote sensing technology, aiming to solve the problems of inefficient, inaccurate, and costly estimation for the GPP of the forest ecosystem.

The present disclosure provides an automatic and accurate estimation method for GPP of a forest ecosystem based on a remote sensing technology, including:
acquiring the real-time position signals of a remote sensing collection device, acquiring the forest map to be estimated from a geographic information database, and displaying the real-time position signals on the map;
collecting the meteorological parameters and the forest characteristic parameters of the forest to be estimated by a remote sensing collection device, and performing a preliminary estimation on the GPP of the forest ecosystem by a ground estimation model according to the meteorological parameters and the forest characteristic parameters, wherein the meteorological parameters include the daily temperature, the daily precipitation and the daily sunshine duration; and the forest characteristic parameters include the normalized difference vegetation index, the leaf area index and the plant coverage density;
collecting the geomorphological features of the map, judging whether to correct the preliminary estimation result according to the geomorphological features, and if the correction is needed, adjusting the preliminary estimation result according to the geomorphologic features, wherein the geomorphologic features include the topographic slope, the topographic aspect, the altitude, the concavity-convexity and the vegetation height; and
storing the adjusted estimation result, and displaying a dynamic fluctuation chart of the adjusted estimation result on a visual device.

Furthermore, the step of acquiring the real-time position signals of a remote sensing collection device, acquiring a forest map to be estimated from a geographic information database, and displaying the real-time position signals on the map includes:
configuring a position module on the remote sensing collection device, communicating the position module with the ground estimation model, and acquiring the position signals of the position module;
dividing the forest map to be estimated evenly into a plurality of unit grids with equal area based on coordinates, matching the position signals with the divided forest map, and assigning the unique number or identification to each unit grid;
receiving and analyzing the position signals from the remote sensing collection device through the ground estimation model, and extracting the real-time longitude information, the latitude information and the altitude information;
matching the received position signals with the grid unit divided on the map by using a coordinate conversion and matching algorithm, and determining the grid units where the position signals are located according to the longitude and latitude of the position signal; and
updating the position of the remote sensing collection device dynamically on the map, marking the grid unit where the remote sensing collection device is located, and displaying the current coordinate, the current altitude and the correspond grid unit number of the device on the map.

Furthermore, the step of collecting meteorological parameters and forest characteristic parameters of a forest to be estimated by a remote sensing collection device, and performing preliminary estimation on the GPP of the forest ecosystem by a ground estimation model according to the meteorological parameters and the forest characteristic parameters includes:
estimating the GPP of the forest ecosystem preliminarily by the following equation:

$$GPP = ( S \times D \times 0.24 ) \times ( α \times NDVI + β ) \times ϵmax \times \{ 1 / [ 1 + {e}^{- k ( T - Topt )} ] \} \times [ P / ( P + P 0 ) ] \times [ LAI / ( 1 + LAI ) ] \times CD .$$

$$ϵmax = ϵ c \times ϵ a \times ϵ b .$$

In the above equation, GPP is the preliminary estimated gross primary productivity of the forest ecosystem, unit: gCm²d⁻¹; S is a solar radiation constant, S=1361W/m²; D is the daily sunshine duration, unit: hour; 0.24=1/2*0.48, wherein 1/2 represents 50% of the total solar radiation converted to photosynthetically active radiation, and 0.48 represents a coefficient for converting W/m² to MJ/m²; α and β are empirical coefficients, α=1.2, β=−0.1; NDVI is the normalized difference vegetation index; ϵmax is a maximum value of light energy utilization efficiency, ϵc is maximum light energy utilization efficiency under astronomical conditions, with a value range of [1.5, 2.5], unit: gCMJ⁻¹; ϵa is a correction coefficient of the utilization efficiency under the daily temperature and daily moisture, with a value range of [0.2, 1.0]; ϵb is a correction coefficient under vegetation conditions, with a value range of [0.5, 1.0]; T is the daily temperature, unit: degree Celsius; Topt is optimal temperature for photosynthesis, with Topt=25 degrees Celsius; k is a temperature sensitivity coefficient, k=0.05; P is the daily precipitation, unit: millimeter; P0 is the water saturation constant, with a value range of [5, 10], unit: millimeter; LAI is the leaf area index; CD is the plant coverage density.

Furthermore, the step of judging whether to correct the preliminary estimation result according to the geomorphological features includes:
judging whether to correct the preliminary estimation result according to the topographic slope, the topographic aspect, the altitude, the concavity-convexity and the vegetation height in turn; and
correcting the preliminary estimation result according to the topographic slope, the topographic aspect, the altitude, the concavity-convexity and the vegetation height in turn according to the judgment result.

Furthermore, the step of judging whether to correct the preliminary estimation result according to the geomorphological features, and if the correction is needed, adjusting the preliminary estimation result according to the geomorphologic features also includes:
if the topographic slope is less than or equal to 5 degrees, the preliminary estimation result is not adjusted, and the preliminary estimation result is taken as the first estimation value GPP1;
if the topographic slope is greater than 5 degrees, the preliminary estimation result is adjusted, and the adjusted value is taken as the first estimation value GPP1;
the equation for correcting the preliminary estimation result according to the topographic slope is as follows:

$$GPP 1 = GPP \times ( 1 + CF 1 ) ;$$

in the above equation, GPP1 is the value after the primary correction of the preliminary estimated GPP of the forest ecosystem, i.e., the first estimation value; GPP is the preliminary estimated gross primary productivity of the forest ecosystem; CF1 is the correction coefficient determined according to the slope type, wherein the value range of CF1 is [0, 0.3];
if the topographic slope is greater than or equal to 5 degrees and less than 15 degrees, the preliminary estimation result is adjusted, and the value range of CF1 is [0.05, 0.15], and for every 1 degree increase in slope, CF1 increases by 0.01; and
if the topographic slope is greater than or equal to 15 degrees, the preliminary estimation result is adjusted, and the value range of CF1 is (0.15, 0.3], and for every 1 degree increase in slope, CF1 increases by 0.03.

Furthermore, the step of judging whether to correct the preliminary estimation result according to the geomorphological features, and if the correction is needed, adjusting the preliminary estimation result according to the geomorphologic features also includes:
the first estimation value GPP1 is adjusted according to the topographic aspect to obtain the second estimation value GPP2, and the calculation equation of the second estimation value is as follows:

$$the south aspect : GPP 2 = GPP 1 \times ( 1 + CFsouth ) ;$$

$$the north aspect : GPP 2 = GPP 1 \times ( 1 + CFnorth ) ;$$

$$the east aspect : GPP 2 = GPP 1 \times ( 1 + CFeast ) ; and$$

$$the west aspect : GPP 2 = GPP 1 \times ( 1 + CFwest ) ;$$

in the above equation, GPP2 is the value after the secondary correction of the preliminary estimated GPP of the forest ecosystem, i.e., the second estimation value; GPP1 is the first estimation value; CFsouth is the correction coefficient of the south aspect, with the value range of [0.10, 0.15]; CFnorth is the correction coefficient of the north aspect, with the value range of [−0.10, −0.15]; CFeast is the correction coefficient of the east aspect, with the value range of [0.05, 0.10]; and CFwest is the correction coefficient of the west aspect, with the value range of [0.05, 0.10];
if the topographic aspect is between two directions, taking the average of the values after the secondary correction of the preliminary estimated GPP of the forest ecosystem at the two directions as the second estimation value GPP2; and if there are multiple topographic aspects in the topographic area, taking the average of
the values after the secondary correction of the preliminary estimated GPP of the forest ecosystem at several aspects as the second estimation value GPP2.

Furthermore, the step of judging whether to correct the preliminary estimation result according to the geomorphological features, and if the correction is needed, adjusting the preliminary estimation result according to the geomorphologic features also includes:
presetting the first preset altitude A1 and the second preset altitude A2, and the first preset altitude A1 is lower than the second preset altitude A2;
if the altitude is less than the first preset altitude A1, the second estimation value GPP2 is not adjusted, and the second estimation value GPP2 is taken as the third estimation value GPP3;
if the altitude is greater than or equal to the first preset altitude A1 and less than or equal to the second preset altitude A2, the second estimation value GPP2 is corrected by the first adjustment coefficient to obtain the third estimation value GPP3; and
if the altitude is greater than or equal to the second preset altitude A1, the second estimation value GPP2 is corrected by the second adjustment coefficient to obtain the third estimation value GPP3;
wherein the first adjustment coefficient is smaller than the second adjustment coefficient.

Furthermore, the step of judging whether to correct the preliminary estimation result according to the geomorphological features, and if the correction is needed, adjusting the preliminary estimation result according to the geomorphologic features also includes:
presetting the first preset concavity-convexity B1 and the second preset concavity-convexity B2, and the first preset concavity-convexity B1 is smaller than the second preset concavity-convexity B2;
if the concavity-convexity is smaller than the first preset concavity-convexity B1, the third estimation value GPP3 is not adjusted, and the third estimation value GPP3 is taken as the fourth estimation value GPP4;
if the concavity-convexity is greater than or equal to the first preset concavity-convexity B1 and smaller than or equal to the second preset concave-concave B2, the third estimation value GPP3 is corrected by the first adjustment coefficient to obtain the fourth estimation value GPP4; and
if the concavity-convexity is greater than or equal to the second preset concavity-convexity B2, the third estimation value is corrected by the second adjustment coefficient to obtain a value after four corrections to obtain the fourth estimation value GPP4;
wherein the first adjustment coefficient is smaller than the second adjustment coefficient.

Furthermore, the step of judging whether to correct the preliminary estimation result according to the geomorphological features, and if the correction is needed, adjusting the preliminary estimation result according to the geomorphologic features also includes:
presetting the first vegetation height value C1, if the vegetation height is lower than or equal to the first vegetation height value C1, the fourth estimation value GPP4 is not adjusted, and the fourth estimation value GPP4 is taken as the final GPP; and
if the vegetation height is higher than the first vegetation height value C1, the fourth estimation value GPP4 is adjusted, and the adjusted fourth estimation value GPP4 is taken as the final GPP.

Furthermore, the step of if the vegetation height is higher than the first vegetation height value C1, the fourth estimation value GPP4 is adjusted, and the adjusted fourth estimation value GPP4 is taken as the final GPP includes:
adjusting the fourth estimation value GPP4 according to the vegetation height, and the adjusted fourth estimation value GPP4 is taken as the final GPP, which is calculated by the following equation:

$$GPP 5 = GPP 4 \times ( 1 + CF 3 ) ;$$

in the above equation, GPP5 is the value after five corrections of the preliminary estimated GPP of the forest ecosystem, i.e., the fifth estimation value; GPP4 is the fourth estimation value; CF3 is the correction coefficient determined according to the vegetation height, wherein the value range of CF5 is [−0.2,0];
presetting the second vegetation height value C2;
if the vegetation height is less than or equal to the first vegetation height value C1, the fourth estimation value GPP4 is not adjusted, that is, CF5=0;
if the vegetation height is greater than the first vegetation height value C1 and less than or equal to the second vegetation height value C2, the fourth estimation value GPP4 is adjusted, and the value range of CF3 is [−0.05,−0.10]; and
if the vegetation height is greater than the second vegetation height value C2, the fourth estimation value GPP4 is adjusted, and the value range of CF3 is (−0.10,−0.20].

Compared with the prior art, the present disclosure has the following beneficial effects:

The automatic and accurate estimation method for GPP of a forest ecosystem based on a remote sensing technology can achieve accurate GPP assessment by integrating the real-time position signals, meteorological parameters, and forest characteristic parameters. The acquisition of the real-time position signals and the display of forest maps in the geographic information database enable the estimation process to have location accuracy and spatial consistency. The meteorological parameters (daily temperature, precipitation and sunshine duration) and forest characteristic parameters (normalized difference vegetation index, leaf area index and plant coverage density) collected through the remote sensing collection device provide the comprehensive data support for the preliminary and accurate estimation of GPP. Geomorphological features such as slope, aspect, altitude, concavity-convexity and vegetation height are taken into account in the correction of the preliminary estimation results, thus improving the accuracy and reliability of the estimation. Finally, the adjusted results are stored and displayed on the visual device, which makes the monitoring and analysis of the forest ecosystem productivity changes more intuitive and convenient. This method not only improves the accuracy of the data, but also improves the real-time response ability to forest ecosystem changes, which has important practical application value for the management and protection for ecology.

### BRIEF DESCRIPTION OF THE DRAWINGS

By reading the detailed description of the preferred embodiments in the following text, various other advantages and benefits will become clear to those skilled in the art. The accompanying drawings are only for the purpose of illustrating preferred embodiments and are not to be considered limiting of the present disclosure. And throughout the entire FIGURE, the same reference symbols are used to represent the same components.

FIG. 1 is a flowchart of an automatic and accurate estimation method for GPP of a forest ecosystem based on a remote sensing technology provided in an embodiment of the present disclosure.

### DETAILED DESCRIPTION OF THE EMBODIMENTS

In the following, the exemplary embodiments of the present disclosure will be described in more detail with reference to the accompanying drawings. Although the exemplary embodiments of the present disclosure are shown in the accompanying drawings, it should be understood that the present disclosure may be implemented in various forms and should not be limited by the embodiments described herein. On the contrary, these embodiments are provided to enable a more thorough understanding of the present disclosure and to fully convey the scope of the present disclosure to those skilled in the art. It should be noted that the embodiments and features in the embodiments of the present disclosure can be combined with each other without conflict. The present disclosure will be described in detail below with reference to the accompanying drawings and in conjunction with embodiments.

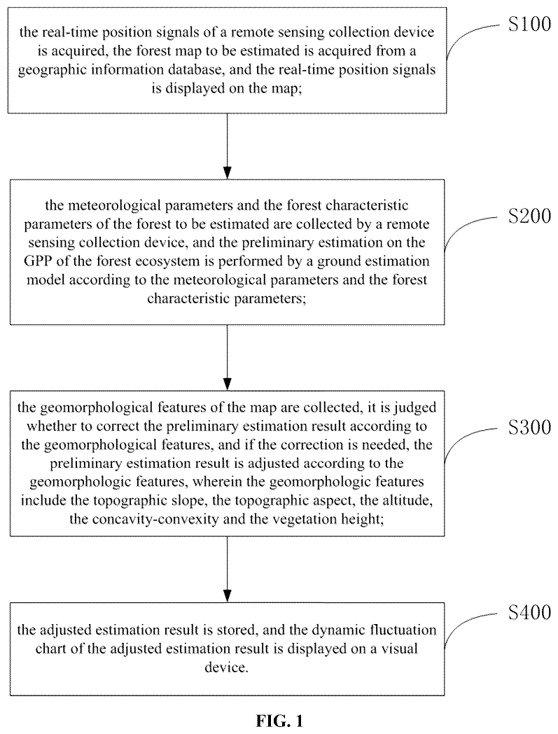

In some embodiments of the present application, as shown in FIG. 1, this present embodiment provides an automatic and accurate estimation method for the GPP of a forest ecosystem based on a remote sensing technology, including the following steps.

S100, the real-time position signals of a remote sensing collection device is acquired, the forest map to be estimated is acquired from a geographic information database, and the real-time position signals is displayed on the map.

S200, the meteorological parameters and the forest characteristic parameters of the forest to be estimated are collected by a remote sensing collection device, and the preliminary estimation on the GPP of the forest ecosystem is performed by a ground estimation model according to the meteorological parameters and the forest characteristic parameters, wherein the meteorological parameters include the daily temperature, the daily precipitation and the daily sunshine duration; and the forest characteristic parameters include the normalized difference vegetation index, the leaf area index and the plant coverage density.

S300, the geomorphological features of the map are collected, it is judged whether to correct the preliminary estimation result according to the geomorphological features, and if the correction is needed, the preliminary estimation result is adjusted according to the geomorphologic features, wherein the geomorphologic features include the topographic slope, the topographic aspect, the altitude, the concavity-convexity and the vegetation height.

S400, the adjusted estimation result is stored, and the dynamic fluctuation chart of the adjusted estimation result is displayed on a visual device.

It can be understood that the automatic and accurate estimation method for the GPP of a forest ecosystem based on a remote sensing technology in the present disclosure can achieve accurate GPP assessment by integrating the real-time position signals, meteorological parameters, and forest characteristic parameters. The acquisition of the real-time position signals and the display of forest maps in the geographic information database enable the estimation process to have location accuracy and spatial consistency. The meteorological parameters (daily temperature, precipitation and sunshine duration) and forest characteristic parameters (normalized difference vegetation index, leaf area index and plant coverage density) collected through remote sensing collection device provide comprehensive data support for the preliminary and accurate estimation of GPP. Geomorphological features such as slope, aspect, altitude, concavity-convexity and vegetation height are taken into account in the correction of the preliminary estimation results, thus improving the accuracy and reliability of the estimation. Finally, the adjusted results are stored and displayed on the visual device, which makes the monitoring and analysis of forest ecosystem productivity changes more intuitive and convenient. This method not only improves the accuracy of the data, but also improves the real-time response ability to forest ecosystem changes, which has important practical application value for the management and protection for ecology. Preferably, the remote sensing collection device includes satellites, unmanned aerial vehicles, and aircraft.

In some embodiments of the present application, the step of acquiring real-time position signals of a remote sensing collection device, acquiring the forest map to be estimated from a geographic information database, and displaying the real-time position signals on the map includes:
a position module is configured on the remote sensing collection device, the position module communicates with the ground estimation model, and the position signals of the position module are acquired;
the forest map to be estimated is divided evenly into a plurality of unit grids with equal area based on coordinates, the position signals are matched with the divided forest map, and a unique number or identification is assigned to each unit grid;
the position signals from the remote sensing collection device are received and analyzed through the ground estimation model, and the real-time longitude information, the latitude information and the altitude information are extracted;
the received position signals are matched with a grid unit divided on the map by using a coordinate conversion and matching algorithm, and the grid unit where the position signals are located is determined according to the longitude and latitude of the position signal; and
the position of the remote sensing collection device is updated dynamically on the map, the grid unit where the remote sensing collection device is located is marked, and the current coordinate, the current altitude and the correspond grid unit number of the device are displayed on the map.

It can be understood that the accurate GPP estimation is achieved by configuring a location module on the remote sensing acquisition device and communicating it with the ground estimation model to obtain the real-time position signals and matching the signals with the forest map in the geographic information database. This method first evenly divides the forest map into multiple grid units and assigns unique numbers to each grid. Then, the real-time longitude information, the latitude information, and the altitude information are matched with the map grid through the coordinate conversion and matching algorithm to ensure accurate and real-time position. The position of remote sensing collection equipment is dynamically updated, and the grid units where the device is located and their detailed coordinates information and altitude information are marked on the map, providing clear spatial orientation and data visualization. This not only improves the accuracy of estimation, but also enhances real-time monitoring capabilities, making the management and analysis of the forest ecosystem more scientific and efficient.

In some embodiments of the present application, the step of collecting meteorological parameters and forest characteristic parameters of a forest to be estimated by a remote sensing collection device, and performing preliminary estimation on the GPP of the forest ecosystem by a ground estimation model according to the meteorological parameters and the forest characteristic parameters includes:
the GPP of the forest ecosystem is estimated preliminarily by the following equation:

$$GPP = ( S \times D \times 0.24 ) \times ( α \times NDVI + β ) \times ϵmax \times \{ 1 / [ 1 + {e}^{- k ( T - Topt )} ] \} \times [ P / ( P + P 0 ) ] \times [ LAI / ( 1 + LAI ) ] \times CD ;$$

$$ϵmax = ϵ c \times ϵ a \times ϵ b .$$

In the above equation, GPP is the preliminary estimated gross primary productivity of the forest ecosystem, unit: gCm²d⁻¹; S is the solar radiation constant, S=1361W/m²; D is the daily sunshine duration, unit: hour; 0.24=1/2*0.48, wherein 1/2 represents 50% of the total solar radiation converted to the photosynthetically active radiation, and 0.48 represents the coefficient for converting W/m² to MJ/m²; α and β are the empirical coefficients, α=1.2, β=−0.1; NDVI is the normalized difference vegetation index; ϵmax is the maximum value of the light energy utilization efficiency, ϵc is the maximum light energy utilization efficiency under the astronomical conditions, with the value range of [1.5, 2.5], unit: gCMJ⁻¹; ϵa is the correction coefficient of the utilization efficiency under the daily temperature and daily moisture, with the value range of [0.2, 1.0]; ϵb is the correction coefficient under the vegetation conditions, with the value range of [0.5, 1.0]; T is the daily temperature, unit: degree Celsius; Topt is the optimal temperature for photosynthesis, with Topt=25 degrees Celsius; k is the temperature sensitivity coefficient, k=0.05; P is the daily precipitation, unit: millimeter; P0 is the water saturation constant, with the value range of [5, 10], unit: millimeter; LAI is the leaf area index; CD is the plant coverage density.

It can be understood that the use of the above equation for the preliminary estimation for the GPP of the forest ecosystem, which combines a variety of key meteorological and forest characteristic parameters, has significant advantages. In the equation, the main factors affecting forest GPP are comprehensively integrated by considering the solar radiation, the sunshine duration, the vegetation index, the light energy utilization efficiency, the daily temperature, the precipitation, the leaf area index and the plant coverage density. Specifically, the equation takes into account the conversion efficiency of photosynthetically active radiation, the impact of environmental conditions on light energy utilization, the optimization effect of temperature on photosynthesis, and the effects of water and plant cover, providing a more accurate estimation of GPP. In addition, ϵmax combines the astronomical conditions, the daily temperature, and the vegetation conditions to make the estimated results more realistic. Through this comprehensive method, the productivity changes of the forest ecosystem can be more accurately reflected, providing strong data support for the forest management and the ecological research. Preferably, the ground estimation model is the equation for calculating GPP.

In some embodiments of the present application, the step of judging whether to correct the preliminary estimation result according to the geomorphological features includes:
it is judged whether to correct the preliminary estimation result according to the topographic slope, the topographic aspect, the altitude, the concavity-convexity and the vegetation height in turn; and
the preliminary estimation result is corrected according to the topographic slope, the topographic aspect, the altitude, the concavity-convexity and the vegetation height in turn according to the judgment result.

It can be understood that the accuracy and reliability of the estimation results can be significantly improved by considering the topographic slope and aspect, the altitude, the concavity-convexity and the vegetation height in turn to determine whether to correct the GPP. First of all, the correction is carryed out according to the topographic slope which can correct the influence of the light and meteorological conditions caused by the change of the topography, so as to reflect the forest productivity more accurately. Then, the consideration of the topographic slope can further adjust the impact caused by the change of illumination angle to ensure the comprehensiveness of the estimation results. Finally, the consideration of the vegetation height can correct the shading effect of tall vegetation on light and radiation, making the results more realistic. The comprehensive application of these factors makes the estimation of GPP more comprehensively reflect the impact of the topography and vegetation conditions on forest productivity, improves the accuracy and practical application value of the data, and provides a more reliable basis for the forest management and the ecological research.

In some embodiments of the present application, the step of judging whether to correct the preliminary estimation result according to the geomorphological features, and if the correction is needed, adjusting the preliminary estimation result according to the geomorphologic features also includes:
if the topographic slope is less than or equal to 5 degrees, the preliminary estimation result is not adjusted, and the preliminary estimation result is taken as the first estimation value GPP1;
if the topographic slope is greater than 5 degrees, the preliminary estimation result is adjusted, and the adjusted value is taken as the first estimation value GPP1;
the equation for correcting the preliminary estimation result according to the topographic slope is as follows:

$$GPP 1 = GPP \times ( 1 + CF 1 ) .$$

In the above equation, GPP1 is the value after the primary correction of the preliminary estimated GPP of the forest ecosystem, i.e., the first estimation value; GPP is the preliminary estimated gross primary productivity of the forest ecosystem; CF1 is the correction coefficient determined according to the slope type, wherein the value range of CF1 is [0, 0.3].

If the topographic slope is greater than or equal to 5 degrees and less than 15 degrees, the preliminary estimation result is adjusted, and the value range of CF1 is [0.05, 0.15], and for every 1 degree increase in slope, CF1 increases by 0.01.

If the topographic slope is greater than or equal to 15 degrees, the preliminary estimation result is adjusted, and the value range of CF1 is (0.15, 0.3], and for every 1 degree increase in slope, CF1 increases by 0.03.

It can be understood that the scheme of correcting GPP based on topographic slope adjusts the preliminary estimation results through the precise correction coefficients, greatly improving the accuracy and reliability of the estimation. Specifically, if the topographic slope is less than or equal to 5 degrees, the impact of slope on the estimation results is relatively small, so no adjustment is needed. However, if the slope exceeds 5 degrees, the impact of slope on the light and meteorological conditions is significant, and the GPP needs to be adjusted. For areas with slopes between 5 degrees and 15 degrees, the correction factor increases linearly with the increase of slope to gradually adapt to the impact of topography on productivity. For areas where the slope increases by more than 1 degree, the increase in correction coefficient is greater to more fully compensate for the impact of slope on the estimation results. This refined correction method can effectively consider the different effects of topography on the light and meteorological conditions, thereby providing more accurate forest productivity assessment, which is helpful for better the forest management and the ecological monitoring.

In some embodiments of the present application, the step of judging whether to correct the preliminary estimation result according to the geomorphological features, and if the correction is needed, adjusting the preliminary estimation result according to the geomorphologic features also includes:
the first estimation value GPP1 is adjusted according to the topographic aspect to obtain the second estimation value GPP2, and the calculation equation of the second estimation value is as follows:

$$the south aspect : GPP 2 = GPP 1 \times ( 1 + CFsouth ) ;$$

$$the north aspect : GPP 2 = GPP 1 \times ( 1 + CFnorth ) ;$$

$$the east aspect : GPP 2 = GPP 1 \times ( 1 + CFeast ) ; and$$

$$the west aspect : GPP 2 = GPP 1 \times ( 1 + CFwest ) .$$

In the above equation, GPP2 is the value after the secondary correction of the preliminary estimated GPP of the forest ecosystem, i.e., the second estimation value; GPP1 is the first estimation value; CFsouth is the correction coefficient of the south aspect, with the value range of [0.10,0.15]; CFnorth is the correction coefficient of the north aspect, with the value range of [−0.10,−0.15]; CFeast is the correction coefficient of the east aspect, with the value range of [0.05, 0.10]; and CFwest is the correction coefficient of the west aspect, with the value range of [0.05, 0.10].

If the topographic aspect is between two directions, taking the average of the values after the secondary correction of the preliminary estimated GPP of the forest ecosystem at the two directions as the second estimation value GPP2.

If there are multiple topographic aspects in the topographic area, taking the average of the values after the secondary correction of the preliminary estimated GPP of the forest ecosystem at several aspects as the second estimation value GPP2.

It can be understood that further correction of the first estimation value GPP1 based on the topographic aspect can significantly improve the accuracy and practicality of the estimation results. Different corrections are made to the south aspect, the north aspect, the east aspect, and the west aspect to ensure accurate reflection of specific impacts on the light and meteorological conditions in each direction. The correction coefficients for the south aspect and north aspect take into account the photosynthetic efficiency under different light conditions, while the correction coefficients for the east aspect and the west aspect take into account the impact of changes in sunlight on GPP. For situations where the topographic aspect is between two directions or there are multiple aspects, taking the average of the secondary correction values can better integrate the effects of different aspects and ensure the overall accuracy of the estimation results. This multilayered correction method makes the estimation of the GPPof the forest more realistic and helps provide more accurate forest management and ecological monitoring data.

In some embodiments of the present application, the step of judging whether to correct the preliminary estimation result according to the geomorphological features, and if the correction is needed, adjusting the preliminary estimation result according to the geomorphologic features also includes:
the first preset altitude A1 and the second preset altitude A2 are preseted, and the first preset altitude A1 is lower than the second preset altitude A2;
if the altitude is less than the first preset altitude A1, the second estimation value GPP2 is not adjusted, and the second estimation value GPP2 is taken as the third estimation value GPP3;
if the altitude is greater than or equal to the first preset altitude A1 and less than or equal to the second preset altitude A2, the second estimation value GPP2 is corrected by the first adjustment coefficient to obtain the third estimation value GPP3; and
if the altitude is greater than or equal to the second preset altitude A1, the second estimation value GPP2 is corrected by the second adjustment coefficient to obtain the third estimation value GPP3.

Wherein the first adjustment coefficient is smaller than the second adjustment coefficient.

It can be understood that this embodiment has multiple advantages by presetting the first preset altitude A1 and the second preset altitude A2 to hierarchically process the estimation of the GPP of the forest ecosystem at different altitudes. Firstly, the estimation efficiency and accuracy are improved by adjusting in stages to avoid the unnecessary correction of the estimation value in the low altitude area. Secondly, the application of different adjustment coefficients in different altitude intervals can help to reflect the complexity of forest ecosystems in high altitude areas more accurately, because the impact of environmental conditions on GPP in high altitude areas is often more significant. Through this hierarchical adjustment method, it is possible to ensure simplified processing of estimates in low altitude areas while providing more precise corrections for high altitude areas, ultimately resulting in more accurate estimation results of GPP of the forest ecosystem.

In some embodiments of the present application, the step of judging whether to correct the preliminary estimation result according to the geomorphological features, and if the correction is needed, adjusting the preliminary estimation result according to the geomorphologic features also includes:
the first preset concavity-convexity B1 and the second preset concavity-convexity B2 are preseted, and the first preset concavity-convexity B1 is smaller than the second preset concavity-convexity B2;
if the concavity-convexity is smaller than the first preset concavity-convexity B1, the third estimation value GPP3 is not adjusted, and the third estimation value GPP3 is taken as the fourth estimation value GPP4;
if the concavity-convexity is greater than or equal to the first preset concavity-convexity B1 and smaller than or equal to the second preset concave-concave B2, the third estimation value GPP3 is corrected by the first adjustment coefficient to obtain the fourth estimation value GPP4; and
if the concavity-convexity is greater than or equal to the second preset concavity-convexity B2, the third estimation value is corrected by the second adjustment coefficient to obtain a value after four corrections to obtain the fourth estimation value GPP4.

Wherein the first adjustment coefficient is smaller than the second adjustment coefficient.

It can be understood that the present disclosure determines whether to perform correction by setting a threshold, avoiding excessive adjustment of estimation results in areas with flat topography or small changes, thereby improving the efficiency and accuracy of the calculation. Secondly, for the complex topography with high concavity-convexity, the classification of adjustment coefficients (the first adjustment coefficient and the second adjustment coefficient) can more flexibly cope with the impact of different topographic conditions on the GPP of the forest ecosystem. Due to the second adjustment coefficient being higher than the first adjustment coefficient, the influence degree of the region with large topographic change on the GPP of the ecosystem can be reflected in a more detailed manner, which not only ensures simplified processing of the flat areas, but also provides precise correction for the complex topography, making the estimated results more in line with actual topographic characteristics.

In some embodiments of the present application, the step of judging whether to correct the preliminary estimation result according to the geomorphological features, and if the correction is needed, adjusting the preliminary estimation result according to the geomorphologic features also includes:
the first vegetation height value C1 is preseted, if the vegetation height is lower than or equal to the first vegetation height value C1, the fourth estimation value GPP4 is not adjusted, and the fourth estimation value GPP4 is taken as the final GPP; and
if the vegetation height is higher than the first vegetation height value C1, the fourth estimation value GPP4 is adjusted, and the adjusted fourth estimation value GPP4 is taken as the final GPP.

In some embodiments of the present application, the step of if the vegetation height is higher than the first vegetation height value C1, the fourth estimation value GPP4 is adjusted, and the adjusted fourth estimation value GPP4 is taken as the final GPP includes:
the fourth estimation value GPP4 is adjusted according to the vegetation height, and the adjusted fourth estimation value GPP4 is taken as the final GPP, which is calculated by the following equation:

$$GPP 5 = GPP 4 \times ( 1 + C F 3 ) .$$

in the above equation, GPP5 is the value after five corrections of the preliminary estimated GPP of the forest ecosystem, i.e., the fifth estimation value; GPP4 is the fourth estimation value; CF3 is the correction coefficient determined according to the vegetation height, wherein the value range of CF5 is [−0.2, 0].

The second vegetation height value C2 is preseted;
if the vegetation height is less than or equal to the first vegetation height value C1, the fourth estimation value GPP4 is not adjusted, that is, CF5=0;
if the vegetation height is greater than the first vegetation height value C1 and less than or equal to the second vegetation height value C2, the fourth estimation value GPP4 is adjusted, and the value range of CF3 is [−0.05,−0.10]; and
if the vegetation height is greater than the second vegetation height value C2, the fourth estimation value GPP4 is adjusted, and the value range of CF3 is (−0.10,−0.20].

It can be understood that this application is targeted at the low vegetation areas and does not need to adjust the estimation values, which reduces unnecessary calculations and improves efficiency. Secondly, if the vegetation height exceeds the first vegetation height value C1, the precise negative adjustments are made based on the specific height to ensure that the estimation results of high vegetation density areas are more practical. By modifying the coefficient CF3 hierarchically, this method can effectively capture the inhibitory effect of vegetation height on photosynthesis and ecosystem production efficiency, so that the final GPP can more accurately reflect the impact of different vegetation heights on productivity. In addition, this hierarchical processing mechanism ensures the flexibility and accuracy of calculations, especially suitable for estimating the GPP of complex ecosystems.

Those skilled in the art should understand that the embodiments of the present application can be provided as methods, systems, or computer program products. Therefore, the present application can adopt the form of a fully hardware implementation, a fully software implementation, or a combination of software and hardware implementation. Moreover, the present application may take the form of a computer program commodity implemented on one or more computer usable storage media (including but not limited to disk storage, CD-ROM, optical storage, etc.) containing computer usable program code.

The present application is described with reference to the flowchart and/or block diagram of the method, device (system), and computer program product according to the embodiments of the present application. It should be understood that each process in the flowchart and/or each block in the block diagram can be implemented by computer program instructions, as well as the combination of processes in the flowchart and/or blocks in the block diagram. These computer program instructions can be provided to a processor of a general-purpose computer, specialized computer, embedded processor, or other programmable data processing device to generate a machine, such that the instructions executed by the processor of the computer or other programmable data processing device generate a device for implementing the functions specified in one or more processes in the flowchart and/or one or more blocks in the block diagram.

These computer program instructions may also be stored in computer-readable memory capable of directing a computer or other programmable data processing device to operate in a specific manner, such that the instructions stored in the computer-readable memory generate a manufactured product comprising instruction devices that implement the functions specified in one or more processes in the flowchart and/or one or more blocks in the block diagram.

These computer program instructions can also be loaded onto a computer or other programmable data processing device, causing a series of operational steps to be executed on the computer or other programmable device to produce computer implemented processing. The instructions executed on the computer or other programmable device provide steps for implementing the functions specified in one or more processes in the flowchart and/or one or more blocks in the block diagram.

Finally, it should be noted that the above embodiments are only used to illustrate the technical solution of the present disclosure and not to limit it. Although the present disclosure has been described in detail with reference to the above embodiments, those skilled in the art should understand that modifications or equivalent substitutions can still be made to the specific embodiments of the present disclosure, and any modifications or equivalent substitutions that do not depart from the spirit and scope of the present disclosure should be covered within the scope of protection of the claims of the present disclosure.

What is claimed is:

1. An automatic and accurate estimation method for gross primary productivity of a forest ecosystem based on a remote sensing technology, comprising:
acquiring real-time position signals of a remote sensing collection device, acquiring a forest map to be estimated from a geographic information database, and displaying the real-time position signals on the map;
collecting meteorological parameters and forest characteristic parameters of a forest to be estimated by a remote sensing collection device, and performing a preliminary estimation on gross primary productivity of a forest ecosystem by a ground estimation model according to the meteorological parameters and the forest characteristic parameters, wherein the meteorological parameters comprise daily temperature, a daily precipitation and daily sunshine duration; and the forest characteristic parameters comprise a normalized difference vegetation index, a leaf area index and plant coverage density;
collecting geomorphological features of the map, judging whether to correct a preliminary estimation result according to the geomorphological features, and if the correction is needed, adjusting the preliminary estimation result according to the geomorphologic features, wherein the geomorphologic features comprise topographic slope, a topographic aspect, an altitude, concavity-convexity and a vegetation height; and
storing an adjusted estimation result, and displaying a dynamic fluctuation chart of the adjusted estimation result on a visual device.

2. The automatic and accurate estimation method for gross primary productivity of a forest ecosystem based on a remote sensing technology according to claim 1, wherein the step of acquiring real-time position signals of a remote sensing collection device, acquiring a forest map to be estimated from a geographic information database, and displaying the real-time position signals on the map comprises:
configuring a position module on the remote sensing collection device, communicating the position module with the ground estimation model, and acquiring position signals of the position module;
dividing the forest map to be estimated evenly into a plurality of unit grids with equal area based on coordinates, matching the position signals with the divided forest map, and assigning a unique number or identification to each unit grid;
receiving and analyzing the position signals from the remote sensing collection device through the ground estimation model, and extracting real-time longitude information, latitude information and altitude information;
matching the received position signals with a grid unit divided on the map by using a coordinate conversion and matching algorithm, and determining grid units where the position signals are located according to longitude and latitude of the position signals; and
updating a position of the remote sensing collection device dynamically on the map, marking the grid unit where the remote sensing collection device is located, and displaying a current coordinate, a current altitude and the correspond grid unit number of the device on the map.

3. The automatic and accurate estimation method for gross primary productivity of a forest ecosystem based on a remote sensing technology according to claim 2, wherein the step of collecting meteorological parameters and forest characteristic parameters of a forest to be estimated by a remote sensing collection device, and performing a preliminary estimation on the gross primary productivity of a forest ecosystem by a ground estimation model according to the meteorological parameters and the forest characteristic parameters comprises:
estimating the gross primary productivity of the forest ecosystem preliminarily by a following equation:
$$GPP = ( S \times D \times 0.24 ) \times ( α \times NDVI + β ) \times ϵmax \times \{ 1 / [ 1 + {e}^{- k ( T - Topt )} ] \} \times [ P / ( P + P 0 ) ] \times [ LAI / ( 1 + LAI ) ] \times CD ;$$
$$ϵmax = ϵ c \times ϵ a \times ϵ b ;$$
in the above equation, GPP is a preliminary estimated gross primary productivity of the forest ecosystem, unit: gCm²d⁻¹; S is a solar radiation constant, S=1361W/m²; D is the daily sunshine duration, unit: hour; 0.24=1/2*0.48, wherein 1/2 represents 50% of the total solar radiation converted to photosynthetically active radiation, and 0.48 represents a coefficient for converting W/m² to MJ/m²; α and β are empirical coefficients, α=1.2, β=−0.1; NDVI is the normalized difference vegetation index; ϵmax is a maximum value of light energy utilization efficiency, ϵc is maximum light energy utilization efficiency under astronomical conditions, with a value range of [1.5, 2.5], unit: gCMJ⁻¹; ϵa is a correction coefficient of the utilization efficiency under the daily temperature and daily moisture, with a value range of [0.2, 1.0]; ϵb is a correction coefficient under vegetation conditions, with a value range of [0.5, 1.0]; T is the daily temperature, unit: degree Celsius; Topt is optimal temperature for photosynthesis, with Topt=25 degrees Celsius; k is a temperature sensitivity coefficient, k=0.05; P is the daily precipitation, unit: millimeter; P0 is the water saturation constant, with a value range of [5, 10], unit: millimeter; LAI is the leaf area index; CD is the plant coverage density.

4. The automatic and accurate estimation method for gross primary productivity of a forest ecosystem based on a remote sensing technology according to claim 3, wherein the step of judging whether to correct a preliminary estimation result according to the geomorphological features comprises:
judging whether to correct the preliminary estimation result according to the topographic slope, the topographic aspect, the altitude, the concavity-convexity and the vegetation height in turn; and
correcting the preliminary estimation result according to the topographic slope, the topographic aspect, the altitude, the concavity-convexity and the vegetation height in turn according to a judgment result.

5. The automatic and accurate estimation method for gross primary productivity of a forest ecosystem based on a remote sensing technology according to claim 4, wherein the step of judging whether to correct a preliminary estimation result according to the geomorphological features, and if the correction is needed, adjusting the preliminary estimation result according to the geomorphologic features also comprises:
if the topographic slope is less than or equal to 5 degrees, the preliminary estimation result is not adjusted, and the preliminary estimation result is taken as a first estimation value GPP1;
if the topographic slope is greater than 5 degrees, the preliminary estimation result is adjusted, and the adjusted value is taken as a first estimation value GPP1;
the equation for correcting the preliminary estimation result according to the topographic slope is as follows:
$$GPP 1 = GPP \times ( 1 + CF 1 ) ;$$
in the above equation, GPP1 is a value after a primary correction of the preliminary estimated gross primary productivity of the forest ecosystem, i.e., a first estimation value; GPP is the preliminary estimated the gross primary productivity of the forest ecosystem; CF1 is a correction coefficient determined according to a slope type, wherein a value range of CF1 is [0, 0.3];
if the topographic slope is greater than or equal to 5 degrees and less than 15 degrees, the preliminary estimation result is adjusted, and a value range of CF1 is [0.05, 0.15], and for every 1 degree increase in slope, CF1 increases by 0.01; and
if the topographic slope is greater than or equal to 15 degrees, the preliminary estimation result is adjusted, and a value range of CF1 is (0.15, 0.3], and for every 1 degree increase in slope, CF1 increases by 0.03.

6. The automatic and accurate estimation method for gross primary productivity of a forest ecosystem based on a remote sensing technology according to claim 5, wherein the step of judging whether to correct a preliminary estimation result according to the geomorphological features, and if the correction is needed, adjusting the preliminary estimation result according to the geomorphologic features also comprises:
adjusting the first estimation value GPP1 according to the topographic aspect to obtain a second estimation value GPP2, and a calculation equation of the second estimation value is as follows:
$$south aspect : GPP 2 = GPP 1 \times ( 1 + CFsouth ) ;$$
$$north aspect : GPP 2 = GPP 1 \times ( 1 + CFnorth ) ;$$
$$east aspect : GPP 2 = GPP 1 \times ( 1 + CFeast ) ;$$
$$west aspect : GPP 2 = GPP 1 \times ( 1 + CFwest ) ;$$
in the above equation, GPP2 is a value after a secondary correction of the preliminary estimated gross primary productivity of the forest ecosystem, i.e., a second estimation value; GPP1 is the first estimation value; CFsouth is a correction coefficient of the south aspect, with a value range of [0.10, 0.15]; CFnorth is a correction coefficient of the north aspect, with a value range of [−0.10,−0.15]; CFeast is a correction coefficient of the east aspect, with a value range of [0.05, 0.10]; and CFwest is a correction coefficient of the west aspect, with a value range of [0.05, 0.10];
if the topographic aspect is between two directions, taking average of values after the secondary correction of the preliminary estimated gross primary productivity of the forest ecosystem at the two directions as a second estimation value GPP2; and
if there are multiple topographic aspects in a topographic area, taking average of the values after the secondary correction of the preliminary estimated gross primary productivity of the forest ecosystem at several aspects as a second estimation value GPP2.

7. The automatic and accurate estimation method for gross primary productivity of a forest ecosystem based on a remote sensing technology according to claim 6, wherein the step of judging whether to correct a preliminary estimation result according to the geomorphological features, and if the correction is needed, adjusting the preliminary estimation result according to the geomorphologic features also comprises:
presetting a first preset altitude A1 and a second preset altitude A2, and the first preset altitude A1 is lower than the second preset altitude A2;
if the altitude is less than the first preset altitude A1, the second estimation value GPP2 is not adjusted, and the second estimation value GPP2 is taken as a third estimation value GPP3;
if the altitude is greater than or equal to the first preset altitude A1 and less than or equal to the second preset altitude A2, the second estimation value GPP2 is corrected by a first adjustment coefficient to obtain a third estimation value GPP3; and
if the altitude is greater than or equal to the second preset altitude A1, the second estimation value GPP2 is corrected by a second adjustment coefficient to obtain a third estimation value GPP3;
wherein the first adjustment coefficient is smaller than the second adjustment coefficient.

8. The automatic and accurate estimation method for gross primary productivity of a forest ecosystem based on a remote sensing technology according to claim 7, wherein the step of judging whether to correct a preliminary estimation result according to the geomorphological features, and if the correction is needed, adjusting the preliminary estimation result according to the geomorphologic features also comprises:
presetting first preset concavity-convexity B1 and second preset concavity-convexity B2, and the first preset concavity-convexity B1 is smaller than the second preset concavity-convexity B2;
if the concavity-convexity is smaller than the first preset concavity-convexity B1, the third estimation value GPP3 is not adjusted, and the third estimation value GPP3 is taken as a fourth estimation value GPP4;
if the concavity-convexity is greater than or equal to the first preset concavity-convexity B1 and smaller than or equal to the second preset concave-concave B2, the third estimation value GPP3 is corrected by a first adjustment coefficient to obtain a fourth estimation value GPP4; and
if the concavity-convexity is greater than or equal to the second preset concavity-convexity B2, the third estimation value is corrected by a second adjustment coefficient to obtain a value after four corrections to obtain a fourth estimation value GPP4;
wherein the first adjustment coefficient is smaller than the second adjustment coefficient.

9. The automatic and accurate estimation method for gross primary productivity of a forest ecosystem based on a remote sensing technology according to claim 8, wherein the step of judging whether to correct a preliminary estimation result according to the geomorphological features, and if the correction is needed, adjusting the preliminary estimation result according to the geomorphologic features also comprises:
presetting a first vegetation height value C1, if the vegetation height is lower than or equal to the first vegetation height value C1, the fourth estimation value GPP4 is not adjusted, and the fourth estimation value GPP4 is taken as final gross primary productivity; and
if the vegetation height is higher than the first vegetation height value C1, the fourth estimation value GPP4 is adjusted, and the adjusted fourth estimation value GPP4 is taken as final gross primary productivity.

10. The automatic and accurate estimation method for gross primary productivity of a forest ecosystem based on a remote sensing technology according to claim 9, wherein the step of if the vegetation height is higher than the first vegetation height value C1, the fourth estimation value GPP4 is adjusted, and the adjusted fourth estimation value GPP4 is taken as final gross primary productivity comprises:
adjusting the fourth estimation value GPP4 according to the vegetation height, and the adjusted fourth estimation value GPP4 is taken as final gross primary productivity, which is calculated by the following equation:
$$GPP 5 = GPP 4 \times ( 1 + CF 3 ) ;$$
in the above equation, GPP5 is a value after five corrections of the preliminary estimated gross primary productivity of the forest ecosystem, i.e., a fifth estimation value; GPP4 is the fourth estimation value; CF3 is a correction coefficient determined according to the vegetation height, wherein a value range of CF5 is [−0.2, 0];
presetting a second vegetation height value C2;
if the vegetation height is less than or equal to the first vegetation height value C1, the fourth estimation value GPP4 is not adjusted, that is, CF5=0;
if the vegetation height is greater than the first vegetation height value C1 and less than or equal to the second vegetation height value C2, the fourth estimation value GPP4 is adjusted, and a value range of CF3 is [−0.05,−0.10]; and
if the vegetation height is greater than the second vegetation height value C2, the fourth estimation value GPP4 is adjusted, and a value range of CF3 is (−0.10,−0.20].
